(19) United States
(12) Patent Application Publication
(10) Pub. No.: US 2015/0181146 A1
(43) Pub. Date: Jun. 25, 2015

(54) AD CONVERTER, AD CONVERSION DEVICE, PHOTOELECTRIC CONVERSION APPARATUS, IMAGING SYSTEM, AND AD CONVERSION METHOD

(71) Applicant: CANON KABUSHIKI KAISHA, Tokyo (JP)

(72) Inventors: Seiji Hashimoto, Yokohama-shi (JP); Daisuke Yoshida, Ebina-shi (JP)

(21) Appl. No.: 14/579,933

(22) Filed: Dec. 22, 2014

(30) Foreign Application Priority Data
Dec. 25, 2013 (JP) 2013-267148

(51) Int. Cl. H04N 5/378; H03M 1/34

(52) U.S. Cl. CPC H04N 5/378; H03M 1/34

(57) ABSTRACT

In a case where a magnitude of an analog signal falls below a first threshold value, a comparator compares the analog signal with a first reference signal so as to obtain a p-bit digital signal. In a case where the magnitude of the analog signal exceeds the first threshold value, the comparator compares the analog signal with a second reference signal, which has a higher rate of change relative to time than the first reference signal, so as to obtain a q-bit digital signal, where q is less than p.

### BACKGROUND OF THE INVENTION

1. Field of the Invention

The present invention relates to an analog to digital (AD) converter, an AD conversion device, a photoelectric conversion apparatus, an imaging system, and an AD conversion method.

2. Description of the Related Art

Japanese Patent Application Laid-Open No. 2010-045789 discusses an image sensor that compares an analog signal with a threshold value obtained by dividing the amplitude of a full scale analog signal by 2^{k}. According to Japanese Patent Application Laid-Open No. 2010-045789, in a case where the analog signal is greater than the threshold value, n-bit digital data on the most significant bit (MSB) side is obtained, and in a case where the analog signal is equal to or less than the threshold value, n-bit digital data on the least significant bit (LSB) side is obtained.

With the image sensor discussed in Japanese Patent Application Laid-Open No. 2010-045789, the digital data on the MSB side and the digital data on the LSB side are both n-bit data. However, in a case of a high luminance signal, data on the MSB side does not need to have a resolution of n-bit. Thus, if n-bit digital data is obtained even in the case of a high luminance signal, excess power may disadvantageously be consumed.

### SUMMARY OF THE INVENTION

The present invention is directed to providing a technique that achieves reducing power consumption while ensuring a wide dynamic range.

According to an aspect of the present invention, a photoelectric conversion apparatus includes a plurality of pixels, a plurality of analog signal output units configured to output analog signals based on the plurality of pixels, a plurality of column signal processing units each including a comparator and provided so as to correspond to the any one of analog signal output units, and a reference signal generation unit configured to generate a first reference signal of which rate of change relative to time varies and a second reference signal of which rate of change relative to time varies that is higher than the rate of change of the first reference signal relative to time. Each of the plurality of column signal processing units compares the analog signal with the first reference signal through the comparator so as to obtain a p-bit digital signal in a case where a magnitude of the analog signal falls below a first threshold value, and compares the analog signal with the second reference signal through the comparator so as to obtain a q-bit digital signal, where q is less than p, in a case where the magnitude of the analog signal exceeds the first threshold value.

Further features of the present invention will become apparent from the following description of exemplary embodiments with reference to the attached drawings.

### BRIEF DESCRIPTION OF THE DRAWINGS

FIG. 1 illustrates a relationship between an analog signal and a reference signal that are to be compared by an AD converter.

FIG. 2 illustrates a configuration example of a photoelectric conversion apparatus.

FIG. 3 illustrates a configuration example of a pixel.

FIG. 4 is a timing chart for describing an operation.

FIG. 5 illustrates a relationship between a signal amplitude of an analog signal and digital data.

FIG. 6 illustrates a detailed configuration example of a digital signal processor (DSP).

FIG. 7 illustrates a change of a reference signal relative to time.

FIG. 8A illustrates a change of a reference signal relative to time according to an exemplary embodiment, and FIG. 8B is a timing chart for describing an operation.

FIG. 9 illustrates a change of a reference signal relative to time.

FIG. 10A illustrates a change in time of ramp signals, FIG. 10B illustrates a relationship between imaging sensitivity and ramp signals, and FIG. 10C illustrates a change in time of ramp signals.

FIG. 11 illustrates a configuration example of a photoelectric conversion apparatus.

FIG. 12 illustrates a detailed configuration example of a column signal processing unit.

FIGS. 13A and 13B each illustrate a process of operation sequence of an imaging system.

FIG. 14 is a timing diagram for an operation.

FIG. 15 is a timing diagram for an operation.

FIG. 16 illustrates a configuration example of a photoelectric conversion apparatus.

FIG. 17 illustrates a configuration example of an amplification circuit.

FIG. 18A illustrates a relationship among imaging sensitivities, amplification gain of an amplification circuit, and ramp signals, and FIG. 18B illustrates a relationship between quantity of incident light and signal levels.

FIG. 19 illustrates a configuration example of an imaging system.

### DESCRIPTION OF THE EMBODIMENTS

Hereinafter, a case in which an AD conversion device is applied to a photoelectric conversion apparatus will be described as an application example of the AD conversion device.

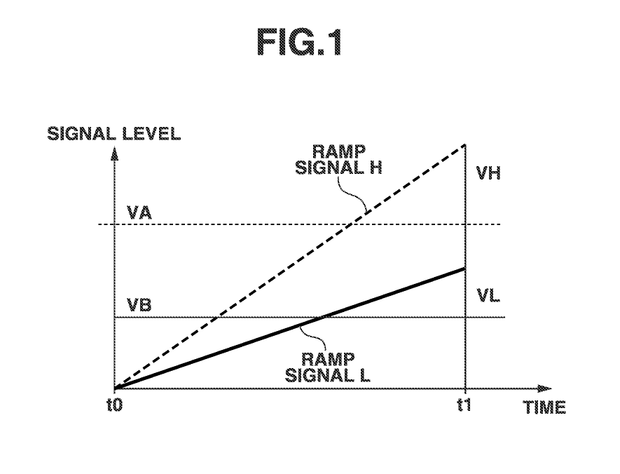

FIG. 1 illustrates a relationship between an analog signal and a reference signal that are to be compared by an AD converter. The horizontal axis indicates time, and the vertical axis indicates a signal level. A ramp signal L and a ramp signal H, as reference signals, are illustrated. The ramp signal H has a maximum value of VH, and thus with the ramp signal H, an AD conversion can be performed on an analog signal having a signal level ranging from 0 to VH. Meanwhile, the maximum value of the signal level of the ramp signal L is VL, which is lower than VH, and in a case where the signal level of an analog signal exceeds VL, AD conversion cannot be performed on the analog signal. In other words, a dynamic range of the AD converter is reduced when the ramp signal L is used, as compared with a case in which the ramp signal H is used. By using the ramp signal L in a case where an analog signal falls below VL and by using the ramp signal H in a case where an analog signal exceeds VL, the dynamic range of the AD converter can be increased while increasing the resolution of a relatively low luminance signal.

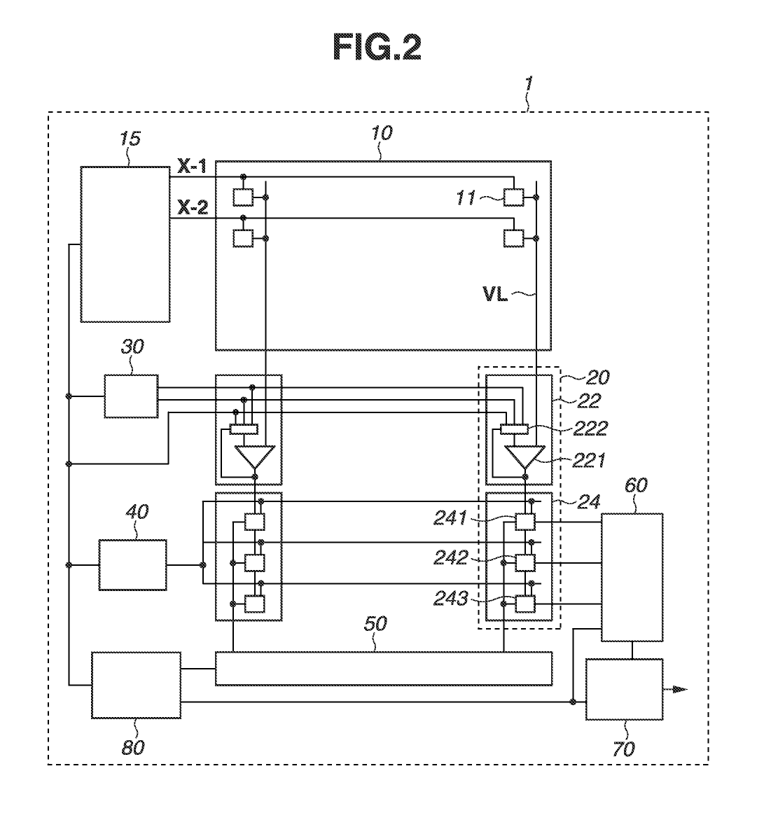

FIG. 2 illustrates a configuration example of a photoelectric conversion apparatus according to a first exemplary embodiment. A photoelectric conversion apparatus includes a pixel array 10, a row selection unit 15, column signal processing units 20, a reference signal generation unit 30, a counter 40, a column selection unit 50, a digital signal processor (DSP) 60, and an output unit 70.

The pixel array 10 includes a plurality of pixels 11 arranged in a matrix. FIG. 2 illustrates the pixels 11 arranged in two columns by two rows. According to the present exemplary embodiment, the pixel array 10 serves as an analog signal output unit.

The column signal processing units 20 are provided so as to correspond to the respective columns of the pixel array 10, and each of the column signal processing units 20 includes a comparison unit 22 and a memory unit 24. The comparison unit 22 includes a comparator 221 and a selection circuit 222. A signal output from the pixel array 10 is input to one of the input terminals of a corresponding comparator 221. Signals output from the reference signal generation unit 30 are input to the other input terminal of the comparator 221 through the selection circuit 222. The reference signal generation unit 30 outputs a signal which is a threshold value and a reference signal of which the signal level varies relative to time. The selection circuit 222 selects one of the signals output from the reference signal generation unit 30 and supplies the selected signal to the other input terminal of the comparator 221.

The counter 40 counts clock signals supplied, for example, from a timing control unit (not illustrated) and outputs a count signal accordingly.

The memory unit 24 includes a flag memory 241, an S memory 242, and an N memory 243. The flag memory 241 stores a flag signal. The S memory 242 and the N memory 243 store the count signal that is supplied from the counter 40 in accordance with an output of the comparator 221, in other words, in accordance with a change in the magnitude relationship between an analog signal and the reference signal.

The column selection unit 50 selects the memory unit 24, and a signal stored in the selected memory unit 24 is then transferred to the DSP 60.

The DSP 60 corrects a signal based on a flag signal. In addition, the DSP 60 may carry out differential processing of a signal stored in the S memory 242 and a signal stored in the N memory 243.

The output unit 70 outputs a signal that has been output from the DSP 60. The output unit 70 may be provided with a buffer function.

A timing generation unit 80 supplies a signal for the operation of the photoelectric conversion apparatus 1.

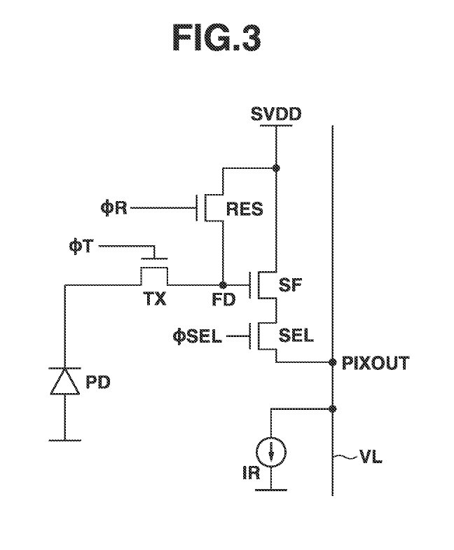

FIG. 3 illustrates a configuration example of the pixel 11 according to the present exemplary embodiment. The pixel 11 includes a photodiode PD, an amplification transistor SF, a transfer transistor TX, a reset transistor RES, and a selection transistor SEL. The transfer transistor TX, the reset transistor RES, and the selection transistor SEL are switched between a conducting state and a non-conducting state through signals φT, φR, and φSEL, respectively. A ground potential is provided to an anode of the photodiode PD, and a cathode of the photodiode PD is connected to a floating diffusion unit FD via the transfer transistor TX. A gate of the amplification transistor SF is connected to the floating diffusion unit FD and is also connected to a power supply SVDD via the reset transistor RES. One of the main nodes of the amplification transistor SF is connected to the power supply SVDD, and the other main node thereof is connected to an output node PIXOUT via the selection transistor SEL. Upon the selection transistor SEL becoming conductive, the amplification transistor SF and a current source IR form a source follower circuit.

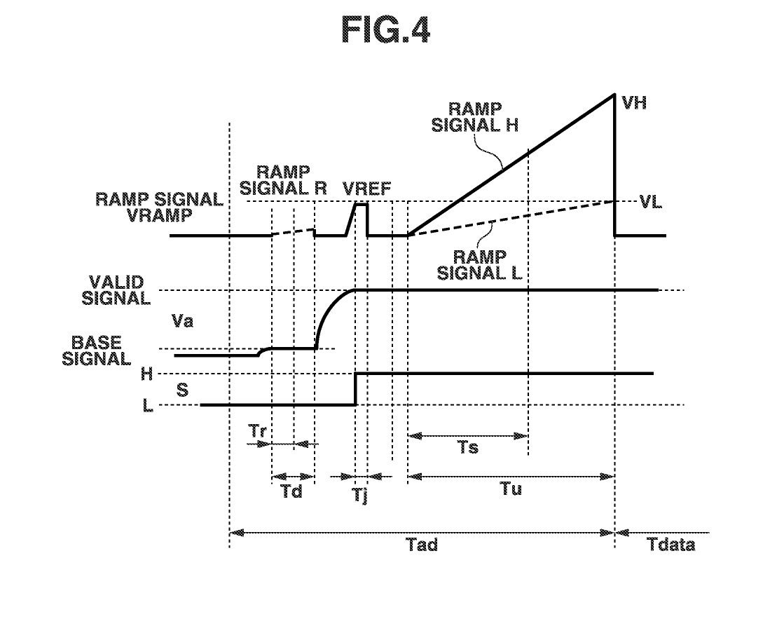

FIG. 4 is a timing chart for describing an operation according to the present exemplary embodiment. Focusing on one of the columns, FIG. 4 illustrates a ramp signal VRAMP that is input to the other input terminal of the comparator 221, a signal output from the pixel 11, in other words, a signal level Va of the one input terminal of the comparator 221, and a signal S provided from the comparator 221 to the selection circuit 222.

A time period Tad is a time period in which AD conversion is performed on an analog signal. In the time period Tad, the signal S is at a low level (hereinafter, indicated as an L level), and thus the selection circuit 222 is provided, among reference signals to be supplied from the reference signal generation unit 30, with a reference signal that has a relatively low rate of change relative to time.

In the pixel 11, upon the gate of the amplification transistor SF being reset by the reset transistor RES, the pixel 11 outputs a base signal. The base signal includes a noise component associated with the reset. After the output of the pixel 11 is stabilized at the base signal, in a time period Td, a ramp signal R is supplied to the comparator 221. The time period Td is a time period in which AD conversion is performed on the base signal. The signal level of the ramp signal R starts to change at a first rate of change relative to time, and the counter 40 starts a count operation. Then, when the ramp signal R exceeds the base signal after a time Tr elapses from the start of the time period Td, the output of the comparator 221 changes, and in response to the change, a count signal is output from the counter 40 and is stored into the N memory 243.

After the time period Td ends, an electric charge that has accumulated in the photodiode PD of the pixel 11 is transferred to the gate of the amplification transistor SF via the transfer transistor TX, and the pixel 11 then outputs a valid signal. The valid signal is a signal in which a component corresponding to an amount of an electric charge that has accumulated in the photodiode PD is superimposed on the base signal.

A time period Tj is a determination time period. In the time period Tj, a comparison voltage VREF as a threshold value is provided to the comparator 221. In the time period Tj, the comparator 221 compares the valid signal with the comparison voltage VREF. If the valid signal exceeds the comparison voltage VREF, the selection circuit 222 is caused to output an H level signal, and a flag signal indicating that the valid signal exceeds the comparison voltage VREF is stored into the flag memory 241. On the other hand, if the valid signal falls below the comparison voltage VREF, the selection circuit 222 is caused to output an L level signal, and a flag signal indicating that the valid signal falls below the comparison voltage VREF is stored into the flag memory 241.

A time period Tu is a time period in which AD conversion is performed on the valid signal. During the time period Tu, the slope of a reference signal to be supplied to the comparator 221 varies in accordance with the output of the selection circuit 222. In a case where the output of the selection circuit 222 is at an H level, in other words, in a case where the valid signal exceeds the comparison voltage VREF, the ramp signal H having a relatively large rate of change relative to time is supplied to the comparator 221. Such a state is indicated by a solid line illustrated in FIG. 4. In a case where the output of the selection circuit 222 is at an L level, in other words, in a case where the valid signal falls below the comparison voltage VREF, the ramp signal L having a relatively small rate of change relative to time is supplied to the comparator 221. Such a state is indicated by a dotted line illustrated in FIG. 4. The signal level of the ramp signal H, which is a second reference signal, starts to change at a second rate of change relative to time, and the counter 40 starts the count operation. Then, when the ramp signal H exceeds the base signal after a time Ts elapses from the start of the time period Tu, the output of the comparator 221 changes, and in response to the change, the count signal is output from the counter 40 and is stored into the S memory 242. Hereinafter, the ramp signal L is also referred to as a first reference signal, and the ramp signal H is also referred to as a second reference signal. According to the present exemplary embodiment, when AD conversion of the valid signal is performed by using the ramp signal H, the operation frequency of the counter 40 is set to one-half of the operation frequency of when AD conversion of the valid signal is performed by using the ramp signal L, which is the first reference signal. Through this, in a case where an analog signal exceeds a threshold value, the analog signal is converted to a digital signal having a smaller number of bits than a digital signal of when the analog signal falls below the threshold value, and thus power consumption can be reduced. A p-bit digital signal is obtained when the ramp signal L is used, and a q-bit digital signal is obtained when the ramp signal H is used, where q is less than p. According to FIG. 4, the first reference signal and the second reference signal both change from a first signal level.

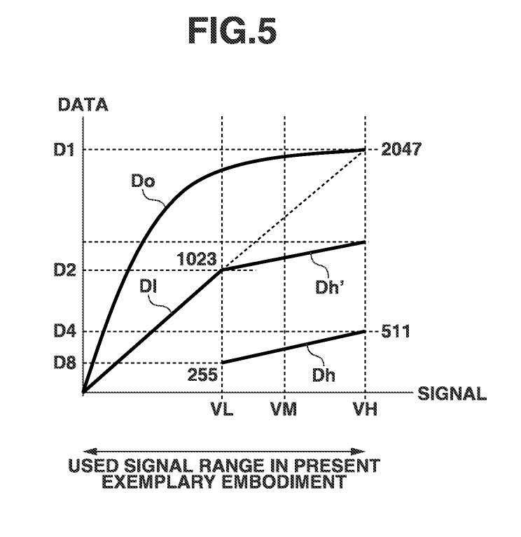

FIG. 5 illustrates a relationship between the signal amplitude of an analog signal and digital data. The horizontal axis indicates the amplitude of the analog signal. The amplitude corresponds to the quantity of light incident on the photodiode PD. The vertical axis indicates a value of a digital signal after AD conversion. Here, D1=2047 (=10¹¹−1) is considered as a full scale of a digital value.

According to FIG. 5, while the analog signal falls within a range up to VL, the analog signal is converted to a 10-bit (=10¹⁰=1024 scale) digital signal by using the ramp signal L. On the other hand, when the analog signal exceeds VL, the analog signal is converted to a digital signal by using the ramp signal H. However, as described above, the operation frequency of the counter 40 is reduced to one-half according to the present exemplary embodiment. In addition, the rate of change of the ramp signal H relative to time is twice the rate of change of the ramp signal L relative to time, and thus the slope of a digital signal to an analog signal that falls within the range from VL to VH is one-fourth of the slope of a digital signal to an analog signal that falls within the range from 0 to VL. Therefore, a digital signal obtained in a case where an analog signal is converted by using the ramp signal H is in a range from D8 (=255=(1024/4)−1) to D4 (=511=(2048/4)−1). This corresponds to a value that is one-fourth of a digital signal to be obtained in a case where AD conversion is performed on an analog signal that falls within a range from VL to VH by using the ramp signal L. When an image is formed from the obtained digital signal, 1023−255=768 is added to a signal of Dh, and thus it is regarded as a signal corresponding to Dh′ in the image. Furthermore, by performing gamma processing on a signal of which characteristics are indicated by DI and Dh′, a signal having characteristics indicated by Do is obtained.

In the meantime, with the technique discussed in Japanese Patent Application Laid-Open No. 2010-045789, even in a case where AD conversion is performed by using a reference signal having a relatively large slope, obtained is a digital signal having the same number of bits as that of a digital signal to be obtained when AD conversion is performed by using a reference signal having a relatively small slope. If this is applied to FIG. 5, an analog signal that falls within a range from VL to VH is converted to 10-bit data ranging from data D2 (1023) to data D1 (2047). If 10-bit data is obtained in this range, however, the power consumption may disadvantageously increase.

On the other hand, according to the present exemplary embodiment, a low luminance component is converted to a 10-bit signal, and a high luminance component is converted to a compressed signal, which can be obtained with smaller power consumption. A change in the luminance in a low luminance component can be easily recognized by human eyes, and thus a low luminance component is an important area in an image. Meanwhile, a change in the luminance in a high luminance component can be recognized less easily by human eyes than a change in the luminance in a low luminance component, and thus a problem is less likely to occur even when a high luminance component is compressed.

As described above, according to the present exemplary embodiment, power consumption can be reduced.

Thus far, for simplifying the description, a case where an analog signal is equal to the threshold value has not been described, but a case where an analog signal exceeds the threshold value and a case where an analog signal falls below the threshold value have been described separately. In a case where an analog signal is equal to the threshold value, processing that is identical to either the processing performed when an analog signal exceeds the threshold value or the processing performed when an analog signal falls below the threshold value may be carried out.

According to FIG. 4, the three ramp signals R, L, and H have been described as reference signals. Of these, the ramp signal R and the ramp signal L are both used to convert an analog signal having a small amplitude, and thus the rate of change thereof relative to time may be set to be the same. By setting the two to be the same, the number of wires for supplying the reference signals can advantageously be reduced. In addition, a circuit for changing the rate of change of a ramp signal relative to time may be provided in the selection circuit 222 of each column, and the ramp signals R, L, and H may be generated in each of the selection circuits 222. In that case, the number of wires connecting the reference signal generation unit 30 to the selection circuit 222 of each column can further be reduced. While the ramp signals R and L change at the first rate of change, the ramp signal H changes at the second rate of change that is higher than the first rate of change.

In addition, the base signal converted by using the ramp signal R contains primarily a noise component and thus does not have a high signal level. Therefore, the allowable maximum value for the ramp signal R can be set lower than the allowable maximum value for the ramp signal L. Through this, the length of the time period Td for AD conversion of the base signal can be reduced.

The comparison voltage VREF as a threshold value to be used when the signal level of the valid signal is determined may be supplied as a fixed voltage or may be generated by stopping the time change of the ramp signal upon the signal level of the ramp signal reaching the threshold value. The comparison voltage VREF may be equal to the allowable maximum value VL for the ramp signal L, but the comparison voltage VREF is desirably lower than the allowable maximum value VL for the ramp signal L. The reason therefore is as follows. Each comparator 221 has an offset, and thus unless the comparison voltage VREF is set sufficiently higher than VL, a correct determination may not be made due to the offset of the comparator 221. Accordingly, the comparison voltage VREF is desirably set to have a signal level that is sufficiently lower than the maximum value VL of the ramp signal L while a variation in the offset of each comparator 221 is taken into consideration.

Thus far, converting the digital signal Dh to Dh′ and performing gamma processing have been described with reference to FIG. 5. Such processing is performed, for example, by the DSP 60. More specifically, in a case where a flag signal output from the flag memory 24 indicates that it has been determined that the analog signal exceeds the threshold value, the digital signal Dh has its level shifted to Dh′.

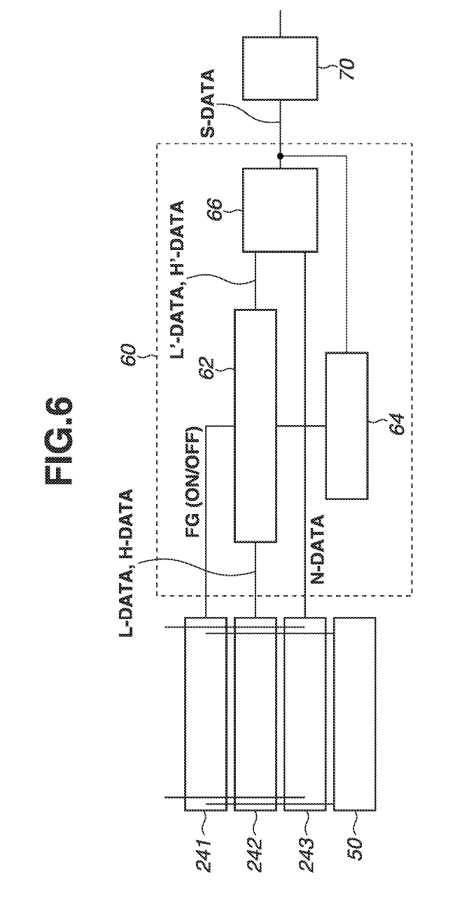

FIG. 6 illustrates a more detailed configuration example of the DSP 60. FIG. 6 illustrates, among the components illustrated in FIG. 2, the comparison unit 22, the flag memory 241, the S memory 242, the N memory 243, the column selection unit 50, the DSP 60, and the output unit 70.

The DSP 60 includes a gain ratio and slope ratio error correction unit 62, a slope ratio error detection unit 64, and a differential processing unit 66. The gain ratio and slope ratio error correction unit 62 identifies a ramp signal that has been used to perform AD conversion of a signal output from the S memory 242 based on a flag signal FG output from the flag memory 241. The gain ratio and slope ratio error correction unit 62 then corrects the signal output from the S memory 242 based on the result of the identification. This enables a digital signal L-DATA obtained by using the ramp signal L and a digital signal H-DATA obtained by using the ramp signal H to be selectively used. This corresponds to the processing of converting the signal Dh to the signal Dh′ as illustrated in FIG. 5.

The slope ratio error detection unit 64 detects the ratio of the rate of change of the ramp signal L relative to time to the rate of change of the ramp signal H relative to time, in other words, detects the slope ratio. According to the present exemplary embodiment, the rate of change of the ramp signal H relative to time is set to be two times greater than the rate of change of the ramp signal L relative to time, but, in reality, the ratio may not be exactly 2:1. Thus, the slope ratio error detection unit 64 detects the slope ratio of the two ramp signals, in other words, detects the ratio of the time rates of change, and the gain ratio and slope ratio error correction unit 62 performs correction processing based on the result of the detection. The differential processing unit 66 performs differential processing of L′-DATA or H′-DATA output from the gain ratio and slope ratio error correction unit 62 and N-DATA output from the N memory 243.

It is difficult to manufacture the apparatus so that the slope ratio of the ramp signal L and the ramp signal H conforms to the design value. An error in the rate of change relative to time generates a signal step around the signal level VL that lies at the boundary between a range where the ramp signal L is used and a range where the ramp signal H is used. It may be possible to measure the error in the rate of change relative to time and then correct the error by the DSP 60, but since a high luminance signal is compressed through AD conversion using the ramp signal H, the error is rarely a problem in an image. Thus, the error does not need to be corrected.

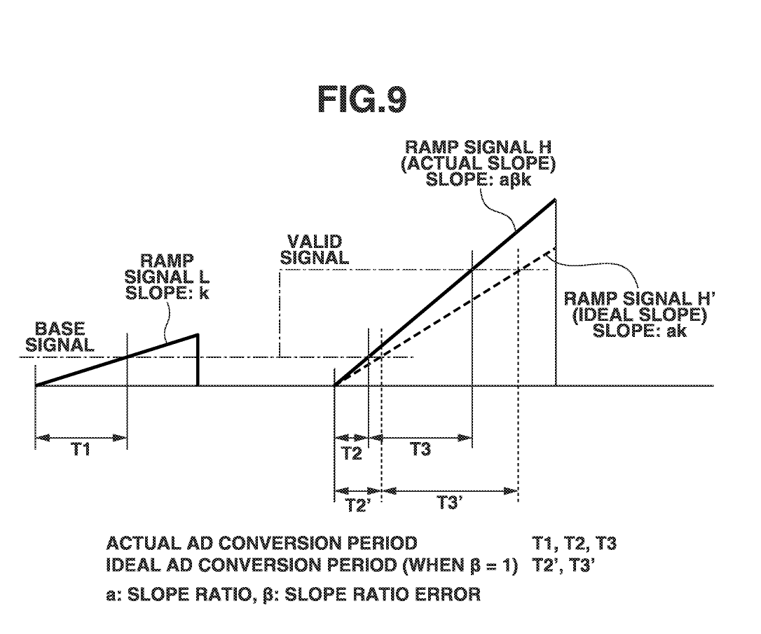

In a case of the ramp signal L and a ramp signal L8 as in an exemplary embodiment illustrated in FIG. 9, a step generated around a signal level V8 lies at an important portion of an image signal, and thus it is better to correct the slope ratio error so as to prevent a deterioration in the image quality. Measurement of the slope ratio error will be described later.

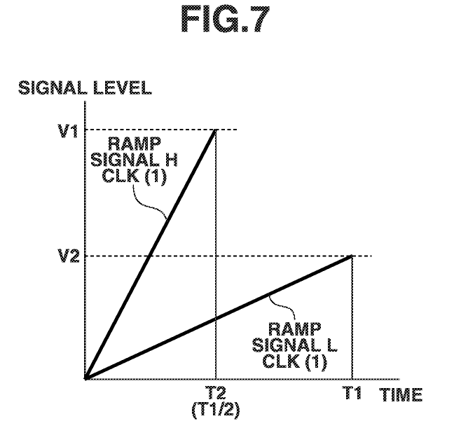

FIG. 7 illustrates changes of reference signals relative to time according to a second exemplary embodiment.

According to the present exemplary embodiment, when AD conversion is performed by using the ramp signal H during the time period Tu illustrated in FIG. 4, the counter 40 is caused to perform the count operation at an operation frequency that is the same as the operation frequency of when AD conversion is performed by using the ramp signal L. The ramp signal H is thus caused to reach the maximum value VH within a time period T2 (=T½) that is one-half of the time it takes for the ramp signal L to reach the maximum value VL.

According to the present exemplary embodiment, the AD conversion time period in which AD conversion is performed by using the ramp signal H can be reduced, which achieves reduction of power consumption.

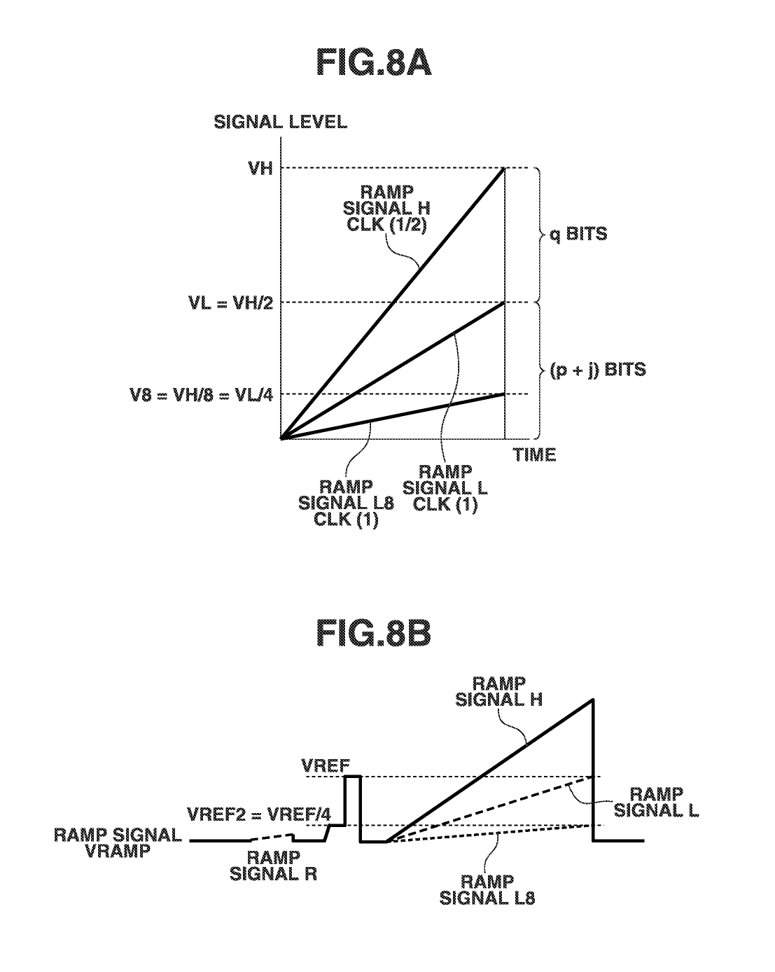

FIG. 8A illustrates changes of reference signals relative to time according to a third exemplary embodiment. Hereinafter, the description centers on features that differ from those of the first exemplary embodiment.

According to the first exemplary embodiment, an example in which AD conversion with the use of the ramp signal L and AD conversion with the use of the ramp signal H while the counter 40 is operated at a frequency that is lower than the frequency to be used when the ramp signal L is used are performed selectively in accordance with the signal level of the valid signal has been described. The present exemplary embodiment differs from the first exemplary embodiment in that, with respect to a signal that falls within a signal range (0 to VL) converted by using the ramp signal L, the valid signal is converted by using a ramp signal L8 having a rate of change relative to time that is lower than that of the ramp signal L in the present exemplary embodiment.

According to the present exemplary embodiment, AD conversion is performed on the valid signal within a range from 0 to V8=VH/8 by using the ramp signal L8 having a rate of change relative to time that is one-fourth of that of the ramp signal L. In such a case, the operation frequency of the counter 40 is the same as that of the case in which the ramp signal L is used.

Relative to the maximum value VH of the ramp signal H, VL is in the relationship of VL=VH/2. In other words, provided that h=1, VL=VH·(½^{h}) holds true. Meanwhile, as for V8, provided that j=2, V8=VH/8={VH·(½^{h})}·(½)=VL·(½^{j}) holds true. Here, a case where the maximum value of an analog signal that can be converted by the AD converter is VH is illustrated as an example.

Thus, suppose the counter 40 outputs a p-bit count signal, a p-bit digital signal is obtained in a case where AD conversion is performed on the valid signal by using the ramp signal L8. In addition, in a case where AD conversion is performed on the valid signal by using the ramp signal L as well, a p-bit digital signal is obtained. A digital signal obtained by using the ramp signal L8 can be regarded as a p-bit signal on the LSB side, and a digital signal obtained by using the ramp signal L can be regarded as a p-bit signal on the MSB side. Thus, by multiplying the p-bit digital signal on the MSB side by 2^{j}, the processing can be regarded as synonymous with performing AD conversion of a valid signal that falls within a range from 0 to VL at a (p+j)-bit resolution. In other words, AD conversion can be performed at a high resolution for a signal range where the signal level is low.

In addition, in a case where AD conversion is performed by using the ramp signal H, q-bit AD conversion is carried out, where q is less than p.

The operation according to the present exemplary embodiment differs from the operation illustrated in FIG. 4 in terms of the ramp signal VRAMP and the output S of the selection circuit 222. FIG. 8B illustrates only the ramp signal VRAMP.

In the determination time period Tj, the reference signal generation unit 30 outputs a second comparison voltage VREF2, which is lower than the first comparison voltage VREF. The comparator 221 compares the valid signal with the second comparison voltage VREF2, which is a second threshold value. If the comparator 221 determines that the valid signal falls below the second comparison voltage VREF2, in the time period Tu for AD conversion, the selection circuit 222 is set to supply the ramp signal L8 to the comparator 221. Then, a signal indicating that the valid signal falls below the second comparison voltage VREF2 is stored in the flag memory 241.

Subsequently, the reference signal generation unit 30 outputs the first comparison voltage VREF. The comparator 221 then compares the valid signal with the first comparison voltage VREF. Based on the result of the comparison, if the comparator 221 determines that the valid signal exceeds the second comparison voltage VREF2 but falls below the first comparison voltage VREF, in the time period Tu for AD conversion, the selection circuit 222 is set to supply the ramp signal L to the comparator 221. Then, a signal indicating that the valid signal falls below the first comparison voltage VREF is stored in the flag memory 241. On the other hand, if the comparator 221 determines that the valid signal exceeds the first comparison voltage VREF, in the time period Tu for AD conversion, the selection circuit 222 is set to supply the ramp signal H to the comparator 221. Then, a signal indicating that the valid signal exceeds the first comparison voltage VREF is stored in the flag memory 241.

Thereafter, the result obtained through AD conversion in the time period Tu for AD conversion is stored into the S memory 242, and the DSP 60 performs differential processing of the stored result and a signal stored in the N memory 243 and performs signal processing, such as offset correction, gain correction, gamma processing, and the like.

According to the present exemplary embodiment, in a case where an analog signal falls below the second threshold value that is less than the first comparison voltage VREF, which is the first threshold value, the analog signal is compared with the ramp signal L8 and a p-bit digital signal is thus obtained. The ramp signal L8 is a third reference signal that has a lower rate of change relative to time than the ramp signal L, which is the first reference signal.

According to the present exemplary embodiment as well, the second comparison voltage VREF2 is desirably set lower than the maximum value of the ramp signal L.

According to the present exemplary embodiment, in a case where an analog signal that is a low luminance signal that falls below the signal level VL is converted to a higher bit signal of a (p+j)-bit signal and in a case where AD conversion is performed on a valid signal that exceeds the signal level VL by using the ramp signal H, the operation frequency of the counter 40 is set to one-half of the operation frequency of when AD conversion is performed by using the ramp signal L, and thus power consumption can be reduced while ensuring a wide dynamic range.

The slope ratio error will be described in further detail.

FIG. 9 illustrates a waveform of a ramp signal in a case where the ramp signal H has an error with respect to an ideal slope. According to FIG. 9, of the timing chart illustrated in FIG. 4, the determination time period Tj is omitted.

According to the example illustrated in FIG. 9, the rate of change, relative to time, of the ramp signal L to be used to perform AD conversion of the base signal is k. In this case, a time period T1 corresponds to the time it takes to perform AD conversion of the base signal.

Meanwhile, the time rate of change of an ideal ramp signal H′ to be used to perform AD conversion of the valid signal is a·k. The rate of change of the actual ramp signal H relative to time has an error of β with respect to the ideal value, and the rate of change of the actual ramp signal H relative to time is a·β˜k. When AD conversion of the valid signal is performed by using the ideal ramp signal H′, the time it takes for the AD conversion is T2′+T3′. On the other hand, when AD conversion of the valid signal is performed by using the actual ramp signal H, the time it takes for the AD conversion is T2+T3.

The slope ratio of the ramp signal L and the ramp signal H′ is a, and thus T1=a·T2′ holds true. Therefore, when differential processing of the valid signal and the base signal is performed, a·(T2′+T3′)−T1=a·T3′ holds true. However, if differential processing of the valid signal obtained and the base signal by the actual ramp signal H is performed, the result has an error with respect to the result obtained when the ideal ramp signal H′ is used. Thus, if the slope ratio error β is known, correction processing of dividing (T2+T3) by β can be performed so that {a·(T2+T3)/β}−T1=a˜T3′ holds true.

A method for detecting the slope ratio β will be described. In brief, a·β can be obtained when a ratio of digital signals obtained by comparing the ramp signal L and the ramp signal H with valid signals of the same level is obtained. As the obtained a·β is divided by the set slope ratio a, the slope ratio error β is obtained.

The slope ratio error β obtained in such a manner is stored in the slope ratio error detection unit 64, and signals may be corrected accordingly. The slope ratio error may be detected at the time of manufacture, or by performing the detection prior to the imaging operation, a slope ratio error that reflects an influence of a temperature condition or the like at the time of imaging may be detected.

According to a fourth exemplary embodiment, combinations of imaging sensitivities set in an imaging system and ramp signals used in the respective imaging sensitivities will be described.

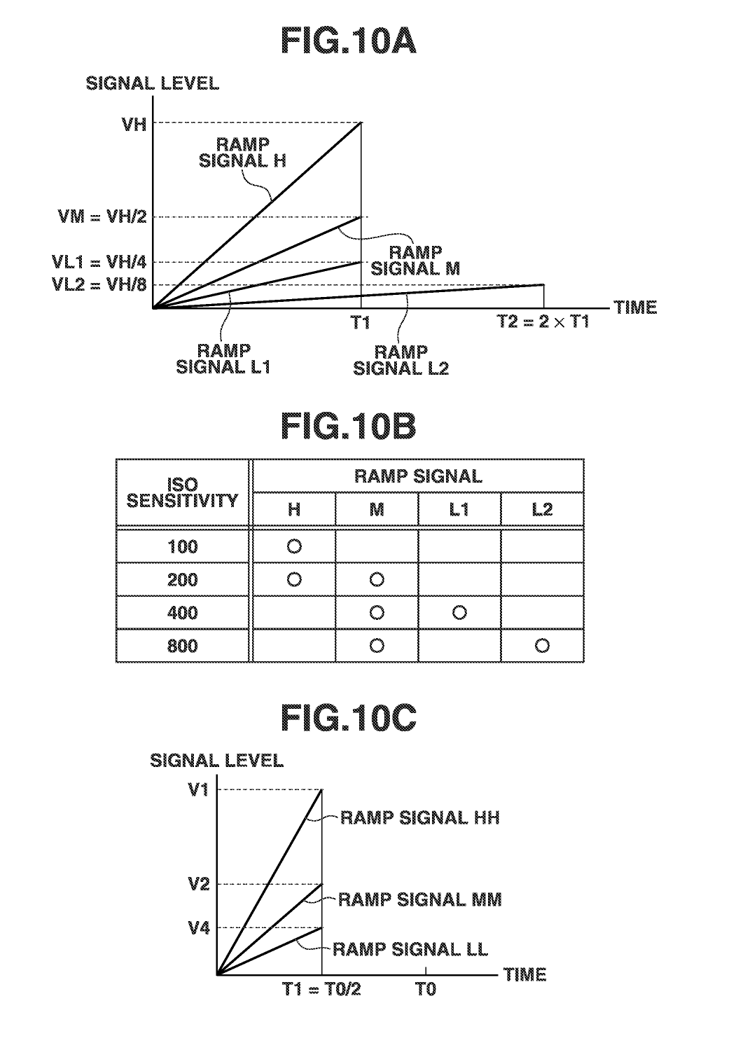

FIG. 10A illustrates time changes of ramp signals according to the present exemplary embodiment. Four ramp signals H, M, L1, and L2 are illustrated. Provided that the maximum value which the ramp signal H can take is VH, the maximum values which the ramp signals M, L1, and L2 can take are, respectively, VM=(VH/2), VL1=(VH/4), and VL2=(VH/8); then, the ramp signals H, M, and L1 each reach the maximum value at a time T1, and the ramp signal L2 reaches the maximum value VL2 at a time T2=2·T1.

FIG. 10B illustrates the imaging sensitivities set in the imaging system and the ramp signals used in the respective imaging sensitivities. Four International Organization for Standardization (ISO) sensitivities 100, 200, 400, and 800 as the imaging sensitivities are listed by row. The ISO sensitivity is so-called the ISO speed. The types of the ramp signals are listed by column. Each cell that contains a circle indicates that the indicated ramp signal is used. More specifically, only the ramp signal H is used when the ISO sensitivity is set to 100, and the ramp signals H and M are used when the ISO sensitivity is set to 200. In addition, the ramp signals M and L1 are used when the ISO sensitivity is 400, and the ramp signals M and L2 are used when the ISO sensitivity is 800.

Typically, the ISO sensitivity is reduced when an image of a high luminance object is to be captured, and thus only the ramp signal H is used when the ISO sensitivity is set to 100, so that AD conversion can be performed on a high luminance signal as well. On the other hand, it is typical to set the ISO sensitivity higher as the luminance of an object decreases, and thus two types of ramp signals are used when the ISO sensitivity is set to 200 or higher. In a case where AD conversion of a valid signal is performed by using two types of ramp signals, the operation frequency of the counter 40 is set lower when a ramp signal having a higher rate of change relative to time is used than when a ramp signal having a lower rate of change relative to time is used. Through this, as in the exemplary embodiments described above, power consumption can be reduced while ensuring a wider dynamic range.

In addition, although a case where two types of ramp signals are used for each of the ISO sensitivities has been described here, as in the third exemplary embodiment, three or more types of ramp signals may be used.

FIG. 10C illustrates time changes of ramp signals in a case where power consumption is reduced by shortening the duration in which the ramp signals change without changing the operation frequency of the counter 40 as in the second exemplary embodiment.

For example, when the ISO sensitivity is set to 200, a ramp signal HH is used in a case where the valid signal exceeds VM, and the ramp signal M is used in a case where the valid signal falls below VM. In addition, when the ISO sensitivity is set to 400, for example, the ramp signal MM is used in a case where the valid signal falls within a range from VL1 to VM, and the ramp signal L1 is used in a case where the valid signal falls below VL1.

According to the present exemplary embodiment as well, power consumption can be reduced while ensuring a wider dynamic range. In addition, by changing a ramp signal to be used in accordance with the setting of the imaging sensitivity, AD conversion suitable for a scene to be captured can be realized.

According to the first to third exemplary embodiments, AD conversion of a valid signal is performed through a ramp comparison method in which the valid signal is compared with a ramp signal. In the fifth exemplary embodiment, an example in which an AD converter of a hybrid AD conversion method in which a successive comparison method and the ramp comparison method are combined is used will be described.

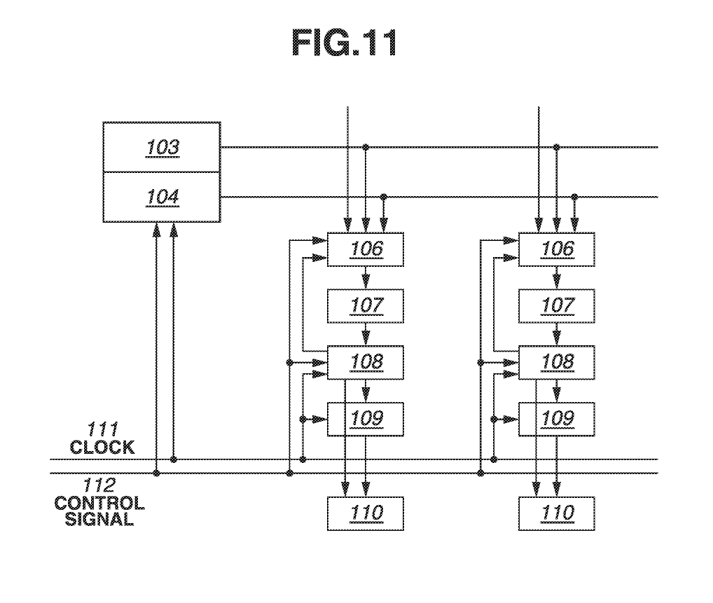

FIG. 11 illustrates a configuration example of a photoelectric conversion apparatus according to the present exemplary embodiment. The photoelectric conversion apparatus illustrated in FIG. 11 differs from the photoelectric conversion apparatus illustrated in FIG. 2 in terms of the configurations of the column signal processing unit and the reference signal generation unit. Other configurations can be identical to those of the photoelectric conversion apparatus illustrated in FIG. 2, and thus illustrations thereof are omitted here.

The reference signal generation unit 30 according to the present exemplary embodiment includes a ramp signal generation unit 104 and a reference voltage generation unit 103.

The column signal processing unit 20 according to the present exemplary embodiment includes a switch and capacitor group 106, a comparator 107, a control circuit 108, a counter 109, and a memory 110.

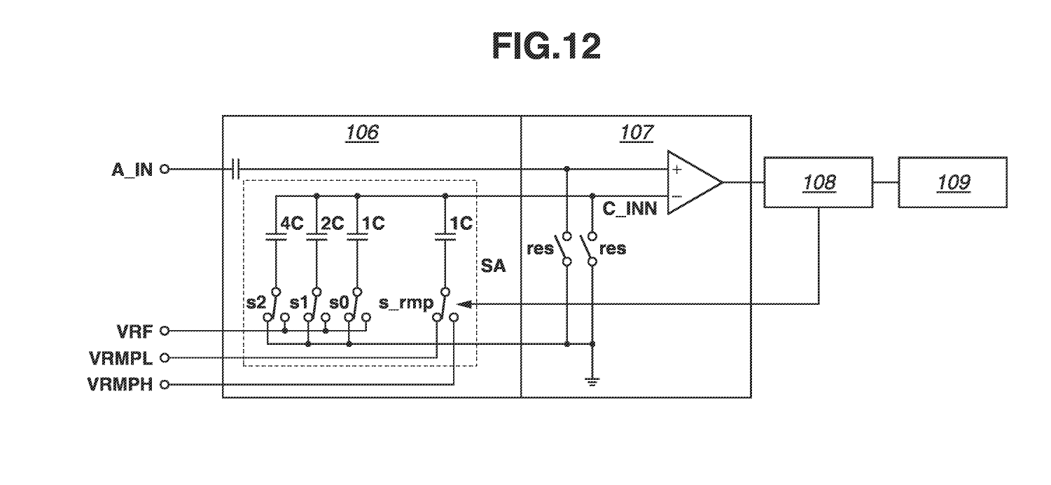

FIG. 12 illustrates a detailed configuration of the column signal processing unit 20. The switch and capacitor group 106 includes a successive comparison capacitance unit SA and an input capacitance Cin. An output from the pixel array 10 is supplied to a non-inverting input terminal of the comparator 107 through the input capacitance Cin.

Capacitance elements having capacitance values 1C, 1C, 2C, and 4C are connected in parallel in the successive comparison capacitance unit SA, and the successive comparison capacitance unit SA is configured to be capable of binary weighting of a reference voltage VRF. According to the present exemplary embodiment, 2-bit successive comparison can be realized. Switches connected in series to the respective capacitance elements having capacitance values of 1C, 2C, and 4C selectively connect the corresponding capacitance element to the reference voltage VRF or a ground potential GND. A switch connected in series to the capacitance element having a capacitance value of 1C is configured to selectively supply VRMPL, which is the ramp signal L, and VRMPH, which is the ramp signal H, to the corresponding capacitance element.

The comparator 107 is configured such a manner that its input terminals can be reset to the ground potential GND, and the output terminal thereof is connected to the control circuit 108.

The counter 109 operates in accordance with the control of the control circuit 108.

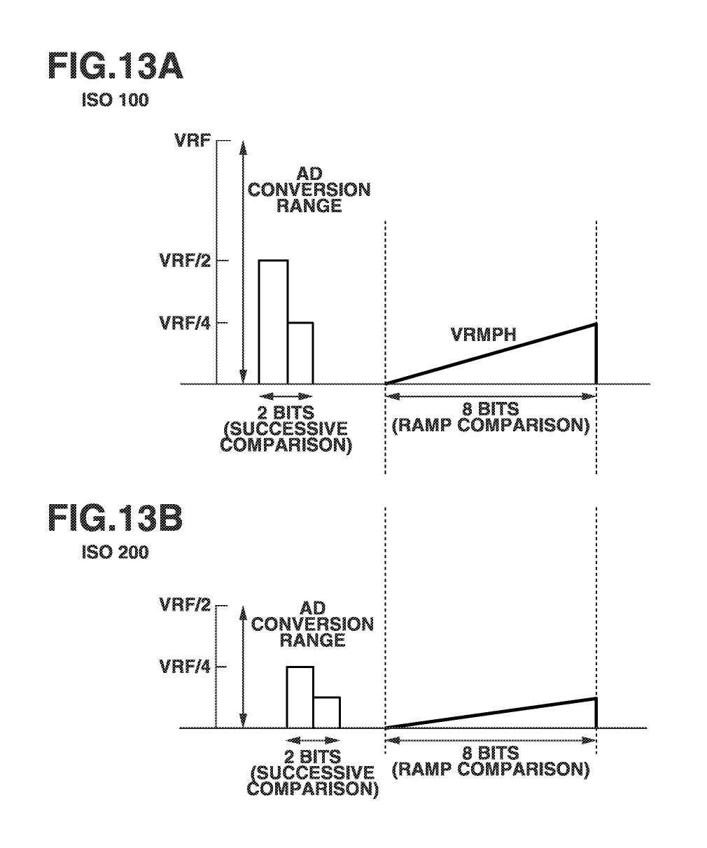

FIG. 13A is illustrates a process for describing operation sequence of the imaging system when the imaging sensitivity is set to the ISO sensitivity 100. A signal supplied from the successive comparison capacitance unit SA to the comparator 107 is illustrated in FIG. 13A. First, voltages VRF/2 and VRF/4 are compared with the valid signal, and thus AD conversion is performed on two higher bits of the valid signal. Hereinafter, this processing is referred to as first processing. Thereafter, a lower analog signal corresponding to the least significant bit of the digital signal obtained through the first processing is compared with the ramp signal VRMPH, and thus AD conversion is performed on the lower eight bits. In this case, the AD conversion range is from 0 to VRF.

On the other hand, FIG. 13B illustrates a process for describing operation sequence of the imaging system when the imaging sensitivity is set to the ISO sensitivity 200. This case differs from the one illustrated in FIG. 13 in that reference voltages of the signals to be compared in the successive comparison operation are VRF/4 and VRF/8 and in that the ramp signal VRMPL is used. However, if such processing is performed, the AD conversion range in the case of the ISO sensitivity 200 becomes one-half of that in the case of the ISO sensitivity 100.

Subsequently, the operation according to the present exemplary embodiment will be described.

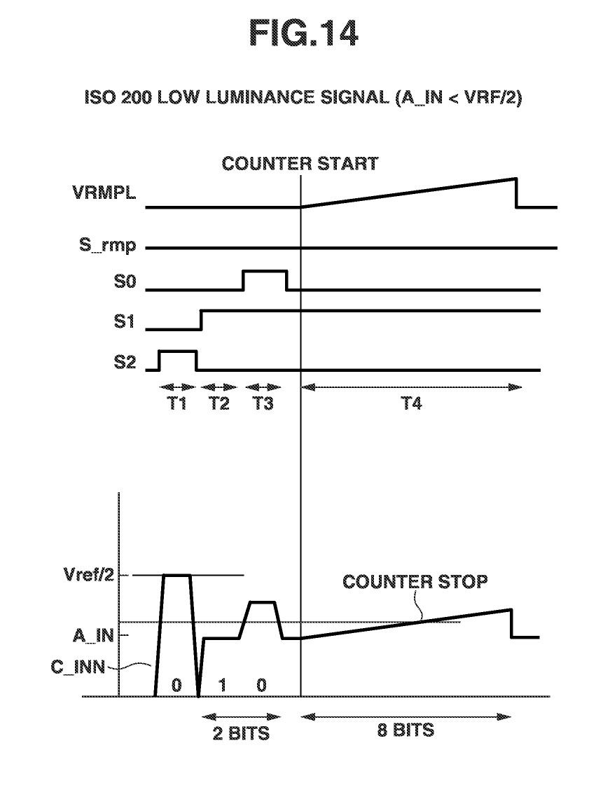

FIG. 14 illustrates a timing chart for describing an operation performed in a case where the valid signal is a low luminance signal that falls below VRF/2 (A_IN<VRF/2) while the ISO sensitivity is set to 200. When signals S0 and S1 are at an H level, the corresponding switches supply the reference voltage VRF to the corresponding capacitance elements, and when the signals S0 and S1 are at a low level, the switches supply the ground potential GND to the corresponding capacitance elements.

In time periods T1 to T3, AD conversion is performed on the valid signal through the successive comparison of two bits. In the time period T1, greater/smaller determination is performed with respect to the voltage VRF/2, and based on the result of the determination, a voltage to be compared with the valid signal in the time periods T2 and T3 is determined. According to FIG. 14, “10” is obtained as a digital code. As it has been found that A IN<VRF/2 holds true based on the result of the determination in the time period T1, the control circuit 108 controls the switches such a manner that the ramp signal VRMPL is supplied to the capacitance element having a capacitance value of 1 C. Through this, in the time period T4, eight-bit AD conversion is performed by using the ramp signal VRMPL that has a relatively low rate of change relative to time.

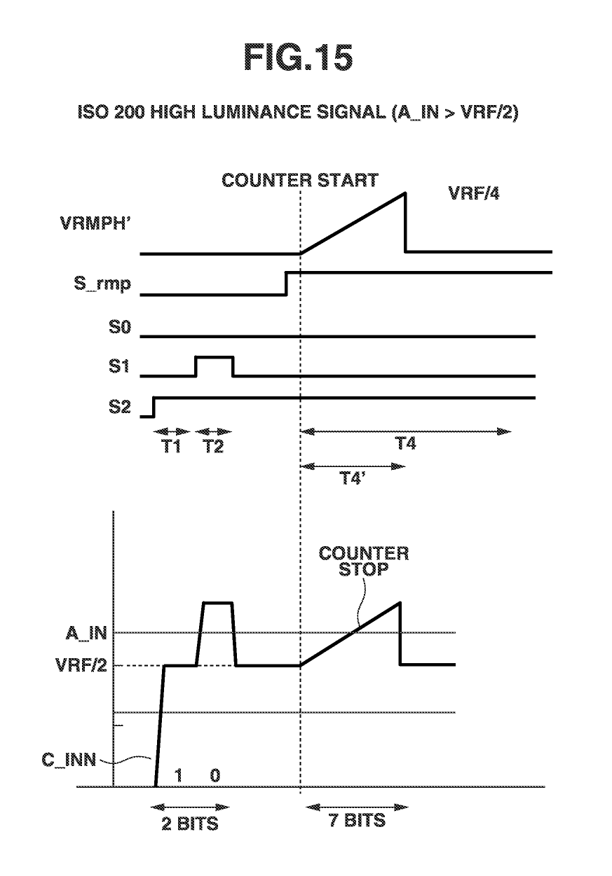

FIG. 15 illustrates a timing chart for describing an operation performed in a case where the valid signal is a high luminance signal that exceeds VRF/2 (A_IN>VRF/2) while the ISO sensitivity is set to 200.

In this case, after AD conversion is performed through successive comparison of two bits, seven-bit AD conversion is performed by using the ramp signal VRMPH having a relatively high rate of change relative to time. In a case where the seven-bit AD conversion is performed, by varying the operation frequency of the counter 109 or by varying the duration in which the ramp signal exhibits a temporal change as described in the exemplary embodiments above, power consumption can be reduced while ensuring a wider dynamic range. In addition, the valid signal that falls within a range from VRF/2 to VRF, on which AD conversion cannot be performed in the example illustrated in FIG. 13, can also be subjected to AD conversion.

In the exemplary embodiments described above, the gain for the signal is increased by reducing the rate of change of the ramp signals relative to time. However, in reality, there exists noise arising due to the comparator or the reference signal generation unit. Thus, in a case where the rate of change of the ramp signals relative to time is small, there is a possibility that a valid signal and noise cannot be differentiated.

Therefore, according to a sixth exemplary embodiment, an amplifier is provided in the analog signal processing unit to reduce an influence of noise.

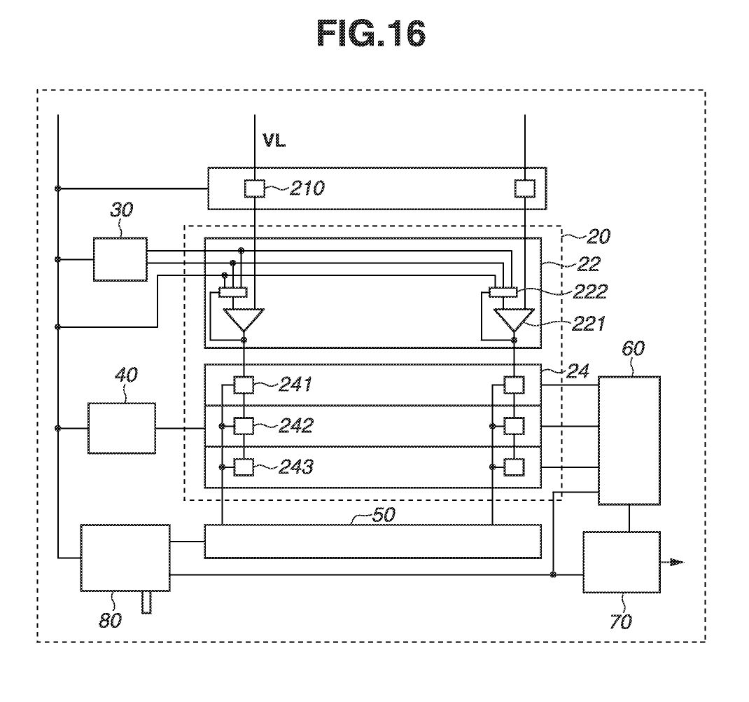

FIG. 16 illustrates a configuration example of a photoelectric conversion apparatus according to the present exemplary embodiment. The photoelectric conversion apparatus illustrated in FIG. 16 differs from the photoelectric conversion apparatus illustrated in FIG. 2 in that an amplification circuit 210 is provided in each column of the pixel array 10.

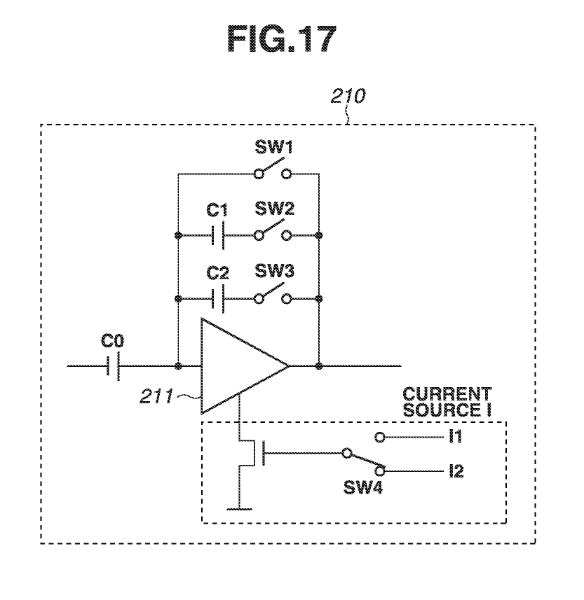

FIG. 17 illustrates a detailed configuration of the amplification circuit 210. The amplification circuit 210 includes a differential amplifier 211, an input capacitance C0, feedback capacitances C1 and C2, switches SW1, SW2, and SW3, and a current source I that supplies a current to the differential amplifier 211. The current source I is a variable current source that is capable of switching the current to be supplied to the differential amplifier 211 between I1 and I2. Here, I2=I½ holds true. Switches SW1 to SW4 are controlled by the timing generation unit 80. The amplification gain of the amplification circuit 210 is determined based on the ratio of the capacitance value of an active feedback capacitance on a feedback path of the differential amplifier 211 to the capacitance value of the input capacitance C0. The amplification circuit 210 can be operated as a clamp circuit through a known method, and thus a signal obtained by subtracting the base signal from the valid signal can be amplified.

Generally, when the ISO sensitivity of an imaging apparatus is changed, the amplification gain of an amplification circuit is switched in a linked manner therewith. In that case, the dynamic range is reduced. According to the present exemplary embodiment, the range in which the amplification gain varies due to a change in the ISO sensitivity is set small, and a wider dynamic range is ensured by varying the rate of change of the ramp signals relative to time.

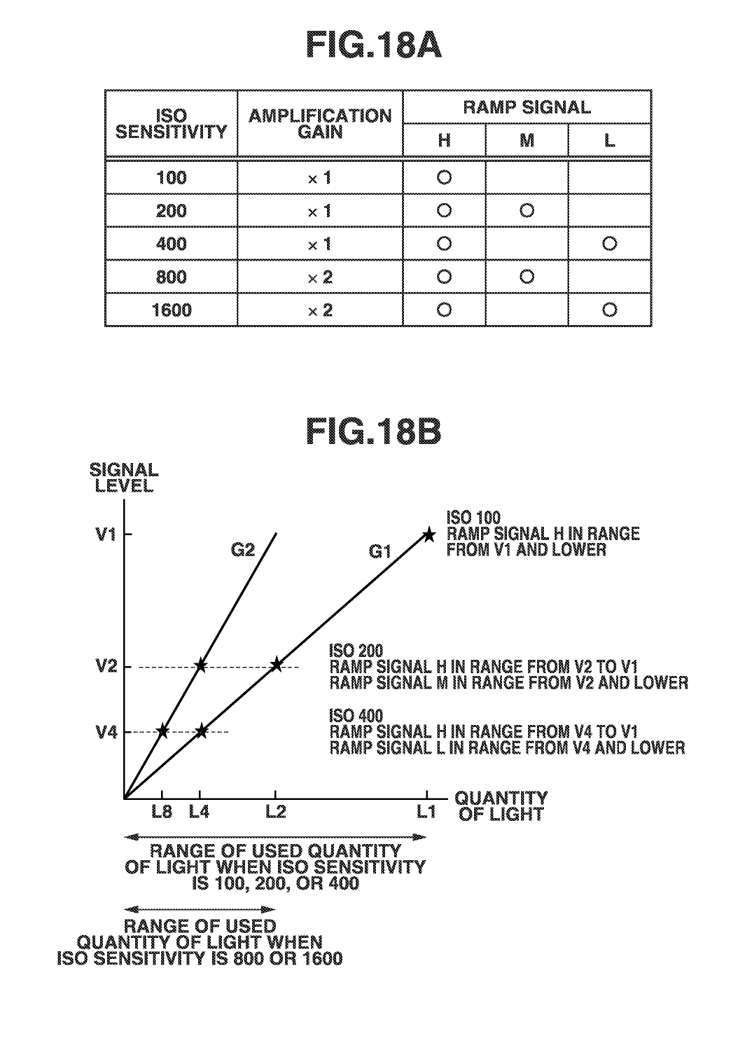

FIG. 18A illustrates a table that indicates the relationship among the ISO sensitivities, the amplification gain of the amplification circuit, and the ramp signals according to the present exemplary embodiment. According to the present exemplary embodiment, the amplification gain is fixed at ×1 when the ISO sensitivity is 100, 200, or 400, and a combination of ramp signals to be used in AD conversion is varied. In a similar manner, the amplification gain is fixed at ×2 when the ISO sensitivity is 800 or 1600, and a combination of ramp signals to be used in AD conversion is varied. Combinations of the ramp signals are identical to those discussed with reference to FIG. 10B, and thus descriptions thereof will be omitted.

FIG. 18B illustrates the relationship between the quantity of light incident on the photoelectric conversion apparatus and the signal level corresponding to the quantity of incident light. When the ISO sensitivity is 100, 200, or 400, the amplification gain is G1=1, and thus the photoelectric conversion apparatus can handle incident light in the quantity ranging from 0 to L1. On the other hand, when the ISO sensitivity is 800 or 1600, the amplification gain is G2=2, and thus the photoelectric conversion apparatus handles incident light in the quantity ranging from 0 to L2 (=L½).

Then, AD conversion is performed only with the ramp signal H when the ISO sensitivity is 100. When the ISO sensitivity is 200, AD conversion is performed on a signal that falls within a range from 0 to V2 by using the ramp signal M, and AD conversion is performed on a signal that falls within a range from V2 to V1 by using the ramp signal H. In a similar manner, when the ISO sensitivity is 400, AD conversion is performed on a signal that falls within a range from 0 to V4 by using the ramp signal L, and AD conversion is performed on a signal that falls within a range from V4 to V1 by using the ramp signal H.

According to the present exemplary embodiment as well, power consumption can be reduced while ensuring a wider dynamic range.

In addition, the current consumed in the amplification circuit 210 may be modified in accordance with the operation mode of the imaging system. More specifically, the current of I2 is supplied to the differential amplifier 211 in order to lower the drive performance of the amplification circuit 210 in a moving image mode, and the current of I1 is supplied to the differential amplifier 211 in a still image mode.

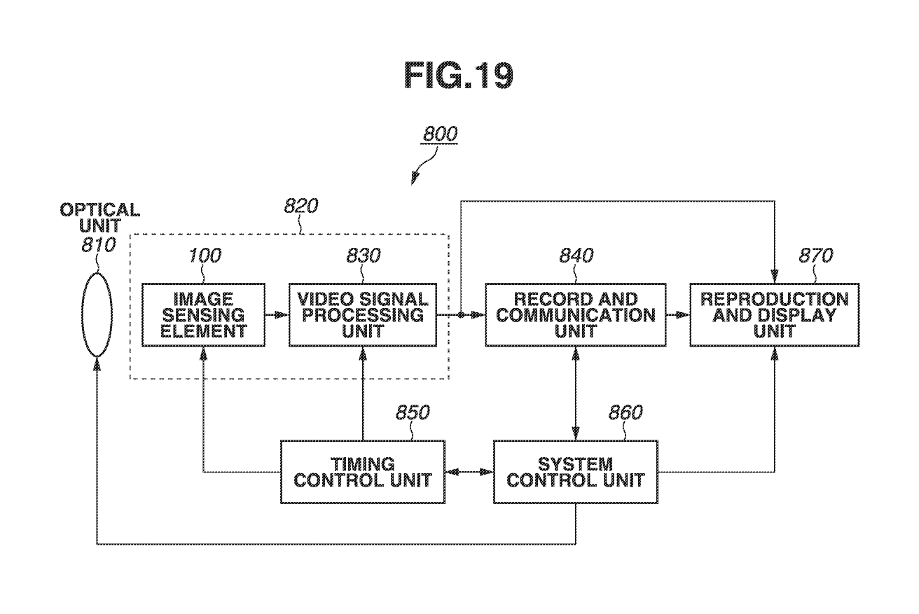

FIG. 19 illustrates a configuration example of an imaging system according to a seventh exemplary embodiment. An imaging system 800 includes, for example, an optical unit 810, an image sensing element 100, a video signal processing unit 830, a record and communication unit 840, a timing control unit 850, a system control unit 860, and a reproduction and display unit 870. An image capturing device 820 includes the image capturing element 100 and the video signal processing unit 830. A photoelectric conversion apparatus described in the preceding exemplary embodiments is used as the image sensing element 100.

The optical unit 810 that is constituted by an optical system, such as a lens, is configured to form an image of light from an object on the pixel array 10 of the image sensing element 100 in which a plurality of pixels is arranged two-dimensionally. The image sensing element 100 outputs a signal in accordance with the image of the light formed on the pixel array 10 at a timing that is based on a signal from the timing control unit 850. The signal output from the image sensing element 100 is input to the video signal processing unit 830, and the video signal processing unit 830 performs signal processing through a method determined by a program and the like. The signal obtained through the processing of the video signal processing unit 830 is transmitted to the record and communication unit 840 as image data. The record and communication unit 840 transmits a signal for forming an image to the reproduction and display unit 870 and causes the reproduction and display unit 870 to reproduce and display a moving image or a still image. The record and communication unit 840 also communicates with the system control unit 860 in response to a signal from the video signal processing unit 830 and records a signal for forming an image into a recording medium (not illustrated).

The system control unit 860 controls the overall operations of the imaging system 800 and controls the driving of the optical unit 810, the timing control unit 850, the record and communication unit 840, and the reproduction and display unit 870. In addition, the system control unit 860 includes a storage device (not illustrated), such as a recording medium, and programs that are necessary for controlling the operation of the imaging system 800 are recorded in the storage device. Furthermore, the system control unit 860 supplies a signal for switching a drive mode, for example, in response to a user operation to the imaging system 800. Specific examples include changing row to be read or row to be reset, changing an angle of view in association with an electronic zoom, and shifting an angle of view in association with electronic image stabilization. The timing control unit 850 controls the drive timings of the image sensing element 100 and the video signal processing unit 830 based on the control of the system control unit 860. In addition, the timing control unit 850 may function as a sensitivity setting unit that sets the imaging sensitivity of the image sensing element 100.

While the present invention has been described in detail based on exemplary embodiments, it is to be understood that the invention is not limited to these specific exemplary embodiments. The above-described exemplary embodiments may be modified or one or more of the above-described embodiments may be combined with each other to create alternative embodiments without departing from the scope of the technical idea of the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-267148 filed Dec. 25, 2013, which is hereby incorporated by reference herein in its entirety.

What is claimed is:

1. An AD converter configured to convert an analog signal to a digital signal,
wherein a magnitude of the analog signal is compared with a first threshold value, and
(a) in a case where the magnitude of the analog signal falls below the first threshold value, the analog signal is converted to a p-bit digital signal, or
(b) in a case where the magnitude of the analog signal exceeds the first threshold value, the analog signal is converted to a q-bit digital signal, where q is less than p.

2. The AD converter according to claim 1, wherein the analog signal is compared with a reference signal of which a signal level varies so as to convert the analog signal to the digital signal.

3. The AD converter according to claim 2,
wherein the analog signal is compared with a rate of change of a first reference signal relative to time so as to convert the analog signal to the p-bit digital signal, and
wherein the analog signal is compared with a rate of change of a second reference signal relative to time so as to convert the analog signal to the q-bit digital signal, the rate of change of the second reference signal relative to time being higher than the rate of change of the first reference signal relative to time.

4. The AD converter according to claim 3, wherein the first threshold value is a signal level that is lower than a maximum value of the second reference signal.

5. The AD converter according to claim 3, wherein, in a case where the rate of change of the second reference signal relative to time is 2^{j} times greater than the rate of change of the first reference signal relative to time, the first threshold value is a value obtained by dividing by 2^{j} a maximum value of an analog signal that can be converted.

6. The AD converter according to claim 3, further comprising:
a counter configured to count a clock signal and output a count signal; and
a memory configured to store the count signal according to changing of a magnitude relationship between an analog signal and the reference signal,
wherein the counter operates in a lower frequency in a case where the analog signal is converted to the p-bit digital signal than in a case where the analog signal is converted to the q-bit digital signal.

7. The AD converter according to claim 3, further comprising:
a correction unit configured to correct a slope ratio error of the first and second reference signals.

8. The AD converter according to claim 3, wherein, in a case where the analog signal falls below a second threshold value that falls below the first threshold value, the analog signal is compared with a third reference signal having a lower rate of change relative to time than the first reference signal so as to convert the analog signal to the p-bit digital signal.

9. The AD converter according to claim 1,
wherein the analog signal is converted to a first digital signal through a successive comparison method as first processing, and
wherein a lower analog signal corresponding to a least significant bit of a digital signal obtained through the first processing is compared with a reference signal of which a signal level varies so as to convert the lower analog signal to a second digital signal.

10. An AD conversion device, comprising:
a plurality of AD converters according to claim 1,
wherein each of the AD converters includes
an analog signal output unit configured to output analog signals, and
a plurality of column signal processing units each provided to as to correspond to the plurality of analog signal output units.

11. The AD conversion device according to claim 10, further comprising:
a reference signal generation unit provided so as to be shared by the plurality of column signal processing units,
wherein the plurality of column signal processing units compares the analog signal with a reference signal of which a signal level varies and which is generated by the reference signal generation unit so as to convert the analog signal to the digital signal.

12. A photoelectric conversion apparatus, comprising:
a plurality of AD conversion devices according to claim 10,
wherein each of the plurality of analog signal output units includes a pixel that output the analog signal based on incident light.

13. An imaging system, comprising:
the photoelectric conversion apparatus according to claim 12;
an optical system configured to form an image on the plurality of pixels; and
a video signal processing unit configured to process a signal output from the photoelectric conversion apparatus so as to generate image data.

14. An AD converter configured to convert an analog signal to a digital signal,
wherein, in a case where a magnitude of the analog signal falls below a first threshold value, the analog signal is converted to a p-bit digital signal by using a first reference signal that varies from a first level, and
wherein, in a case where the magnitude of the analog signal exceeds the first threshold value, the analog signal is converted to a q-bit digital signal, where q is less than p, by using a rate of change of a second reference signal relative to time, the rate of change of the second reference signal relative to time being higher than a rate of change of the first reference signal relative to time.

15. An imaging system, comprising:
a photoelectric conversion apparatus; and
a sensitivity setting unit configured to set an imaging sensitivity of the photoelectric conversion apparatus,
wherein the photoelectric conversion apparatus includes
a plurality of analog signal output units each including a pixel that outputs an analog signal based on incident light, and
a plurality of column signal processing units each provided so as to correspond to any one of the plurality of analog signal output units,
wherein each of the column signal processing units
compares the analog signal with a rate of change of a first reference signal relative to time so as to convert the analog signal to a p-bit digital signal, and
compares the analog signal with a rate of change of a second reference signal relative to time so as to convert the analog signal to a q-bit digital signal, where q is less than p, the rate of change of the second reference signal relative to time being higher than the rate of change of the first reference signal relative to time, and
wherein combinations of the rate of change of the first reference signal relative to time and the rate of change of the second reference signal relative to time in different imaging sensitivities differ from one another.
